(19) United States
(12) Patent Application Publication
(10) Pub. No.: US 2024/0234652 A9
(43) Pub. Date: Jul. 11, 2024

(54) MICRO LIGHT-EMITTING DIODE DISPLAY DEVICE

(71) Applicant: AUO Corporation, Hsin-Chu (TW)

(72) Inventors: Bin-Cheng LIN, Hsin-Chu (TW); Chieh-Ming Chen, Hsin-Chu (TW); Bo-Ru Jian, Hsin-Chu (TW); Chi-Sheng Liao, Hsin-Chu (TW); Ta-Wen Liao, Hsin-Chu (TW)

(21) Appl. No.: 18/489,890

(22) Filed: Oct. 19, 2023

(30) Foreign Application Priority Data
Oct. 25, 2022 (TW) 111140484

(51) Int. Cl. H01L 33/56; H01L 25/075; H01L 33/54

(52) U.S. Cl. CPC H01L 33/56; H01L 25/0753; H01L 33/54

(57) ABSTRACT

A micro light-emitting diode display device includes a substrate, a first planarization layer, a first light-emitting element, and a second planarization layer. The first planarization layer is disposed on the substrate and has a first opening. The first opening has a first opening inner wall. The first light-emitting element is disposed on the substrate, in the first opening, and separated from the first opening inner wall. The second planarization layer is disposed on the substrate and between the first planarization layer and the first light-emitting element. The second planarization layer is in contact with the first light-emitting element.

### CROSS-REFERENCE TO RELATED APPLICATION

This application claims priority to Taiwan Application Serial Number 111140484, filed Oct. 25, 2022, which is herein incorporated by reference.

### BACKGROUND

### Technical Field

The present disclosure relates to a micro light-emitting diode display device.

### Description of Related Art

Micro light-emitting diodes (μLED) have good stability and long lifespan. Also, micro light-emitting diodes have the advantage of low energy consumption, high resolution, and high color saturation.

However, as the critical dimensions of micro light-emitting diodes reduce, the way of effectively conducting mass transfer has become a bottleneck in increasing productivity. For example, if micro light-emitting diodes are not precisely picked up or not properly placed during mass transfer, the micro light-emitting diodes may tilt or fall over. This may lead to malfunction of the micro light-emitting diodes after connection and encapsulation, thus reducing the production yield of micro light-emitting diode display devices.

Accordingly, how to provide a micro light-emitting diode display device to solve the aforementioned problems becomes an important issue to be solved by those in the industry.

### SUMMARY

An aspect of the disclosure is to provide a micro light-emitting diode display device that may efficiently solve the aforementioned problems.

According to an embodiment of the disclosure, a micro light-emitting diode display device includes a substrate, a first planarization layer, a first light-emitting element, and a second planarization layer. The first planarization layer is disposed on the substrate and has a first opening. The first opening has a first opening inner wall. The first light-emitting element is disposed on the substrate, in the first opening, and separated from the first opening inner wall. The second planarization layer is disposed on the substrate and between the first planarization layer and the first light-emitting element. The second planarization layer is in contact with the first light-emitting element.

In an embodiment of the disclosure, the second planarization layer is in contact with the first opening inner wall.

In an embodiment of the disclosure, the second planarization layer surrounds the first light-emitting element.

In an embodiment of the disclosure, a contact angle between the second planarization layer and the first light-emitting element is smaller than a contact angle between the first planarization layer and the substrate.

In an embodiment of the disclosure, the second planarization layer extends from the first opening and at least partially overlaps a top surface of the first planarization layer.

In an embodiment of the disclosure, the micro light-emitting diode display device further includes a first protective layer covering the first planarization layer and the second planarization layer.

In an embodiment of the disclosure, the micro light-emitting diode display device further includes a second light-emitting element and a third light-emitting element. The second light-emitting element and the third light-emitting element are disposed in the first opening.

In an embodiment of the disclosure, the micro light-emitting diode display device further includes a second light-emitting element and a third light-emitting element. The first planarization layer further includes a second opening and a third opening. The second light-emitting element is disposed in the second opening. The third light-emitting element is disposed in the third opening. The second planarization layer is disposed in the second opening and the third opening.

In an embodiment of the disclosure, the micro light-emitting diode display device further includes a third planarization layer. The third planarization layer at least partially overlaps a top surface of the first planarization layer and is in contact with the first light-emitting element.

In an embodiment of the disclosure, the micro light-emitting diode display device further includes a first protective layer covering the first planarization layer and the second planarization layer.

In an embodiment of the disclosure, the micro light-emitting diode display device further includes a second protective layer covering the third planarization layer.

In an embodiment of the disclosure, a contact angle between the third planarization layer and the first light-emitting element is smaller than a contact angle between the first planarization layer and the substrate.

In an embodiment of the disclosure, at least one of the first planarization layer and the second planarization layer includes a light-transmitting material.

In an embodiment of the disclosure, a light transmission of the first planarization layer and a light transmission of the second planarization layer are in a range of 95% and 99%.

In an embodiment of the disclosure, the first planarization layer and the second planarization layer include acrylic resin.

According to another embodiment of the disclosure, a micro light-emitting diode display device includes a substrate, a first planarization layer, a plurality of light-emitting elements, and a second planarization layer. The first planarization layer is disposed on the substrate. The first planarization layer has a plurality of openings with corresponding opening inner walls. The plurality of light-emitting elements is disposed on the substrate. The plurality of light-emitting elements is separated from the corresponding opening inner walls of the plurality of openings. The second planarization layer is disposed in the plurality of openings. The second planarization layer is in contact with the corresponding opening inner walls of the plurality of openings. The second planarization layer laterally wraps the plurality of light-emitting elements. The second planarization layer is in contact with each of the plurality of light-emitting elements.

In an embodiment of the disclosure, a top surface of the first planarization layer is substantially level with a top surface of at least one of the plurality of light-emitting elements.

In an embodiment of the disclosure, a contact angle between the second planarization layer and at least one of the plurality of light-emitting elements is smaller than a contact angle between the first planarization layer and the substrate.

In an embodiment of the disclosure, each of the plurality of light-emitting elements corresponds to one of the plurality of openings. Each of the plurality of light-emitting elements is disposed in its corresponding opening.

In an embodiment of the disclosure, at least two of the plurality of light-emitting elements are disposed in one of the plurality of openings. The second planarization layer is disposed between any adjacent two light-emitting elements in the one of the plurality of openings.

Accordingly, in some embodiments of the micro light-emitting diode display devices of the present disclosure, by disposing an inner planarization layer and an outer planarization layers having different viscosities, the structure around the micro light-emitting diodes may be properly padded within two processes, thereby facilitating the formation of the conductive layer as well as the connection and protection of the electrodes of the micro light-emitting diodes. Specifically, an outer planarization layer with a high viscosity is firstly formed in one process to pad the overall structure. Then, an inner planarization layer with a low viscosity is formed in another process to fill the gap around the micro light-emitting diodes and laterally wrap the micro light-emitting diodes. Compared with currently commonly applied technologies, the micro light-emitting diode display devices according to some embodiments of the present disclosure can simplify manufacturing processes and improve productivity while maintaining rigid cover of the micro light-emitting diodes. Moreover, by using materials with a low film thickness and a low viscosity to form the inner planarization layer, a gentle taper can be formed at the interfaces between any two of the inner planarization layer, the light-emitting element, and the outer planarization layer. Thus, the height difference throughout the structure that may adversely affect the electrode connection during the formation of the conductive layer is reduced.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a partial cross-sectional view of a micro light-emitting diode display device according to an embodiment of the present disclosure;

FIG. 2 is a partial enlarged view of a micro light-emitting diode display device according to an embodiment of the present disclosure;

FIG. 3 is a partial enlarged view of a micro light-emitting diode display device according to an embodiment of the present disclosure;

FIG. 4 is a partial cross-sectional view of a micro light-emitting diode display device according to an embodiment of the present disclosure;

FIG. 5 is a partial cross-sectional view of a micro light-emitting diode display device according to an embodiment of the present disclosure;

FIG. 6 is a partial cross-sectional view of a micro light-emitting diode display device according to an embodiment of the present disclosure;

FIG. 7 is a partial top view of a micro light-emitting diode display device according to an embodiment of the present disclosure;

FIG. 8 is a partial cross-sectional view of a micro light-emitting diode display device according to an embodiment of the present disclosure;

FIG. 9 is a partial top view of a micro light-emitting diode display device according to an embodiment of the present disclosure;

FIG. 10 is a partial cross-sectional view of a micro light-emitting diode display device according to an embodiment of the present disclosure;

FIG. 11 is a partial top view of a micro light-emitting diode display device according to an embodiment of the present disclosure;

FIG. 12 is a partial cross-sectional view of a micro light-emitting diode display device according to an embodiment of the present disclosure;

FIG. 13 is a partial enlarged view of a micro light-emitting diode display device according to an embodiment of the present disclosure;

FIG. 14 is a partial cross-sectional view of a micro light-emitting diode display device according to an embodiment of the present disclosure;

FIG. 15 is a partial enlarged view of a micro light-emitting diode display device according to an embodiment of the present disclosure; and

FIG. 16 is a partial cross-sectional view of a micro light-emitting diode display device according to an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

Micro light-emitting diodes (μLED) have good stability and long lifespan. Also, micro light-emitting diodes have the advantage of low energy consumption, high resolution, and high color saturation. However, as the critical dimensions of micro light-emitting diodes reduce, the way of effectively conducting mass transfer has become a bottleneck in increasing productivity. For example, if electrodes of the micro light-emitting diodes are not properly connected and protected after mass transfer, the micro light-emitting diodes may not be driven.

Therefore, some embodiments of the present disclosure provide a micro light-emitting diode display device having an inner planarization layer and an outer planarization layer, so as to improve productivity while simplifying manufacturing processes.

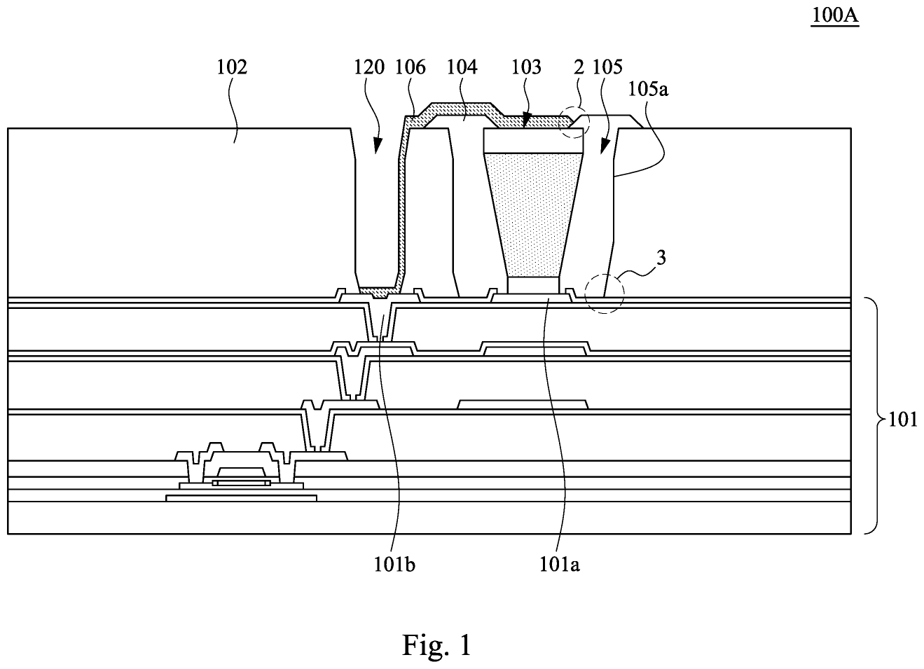

Reference is made to FIG. 1. FIG. 1 is a partial cross-sectional view of a display device 100A according to an embodiment of the present disclosure. As shown in FIG. 1, the display device 100A includes a substrate 101, a first planarization layer 102, a first light-emitting element 103, and a second planarization layer 104. The substrate 101 includes a driving circuit layer. An electrode pad 101a and an electrode pad 101b are disposed in the substrate 101. The first planarization layer 102, the first light-emitting element 103, and the second planarization layer 104 are disposed on the substrate 101. The first planarization layer 102 has a first opening 105. The first light-emitting element 103 is disposed in the first opening 105. However, the first light-emitting element 103 is separated from a first opening inner wall 105a of the first opening 105. The first planarization layer 102 has a through hole 120. The through hole 120 exposes the electrode pad 101b in the substrate 101. The second planarization layer 104 is disposed between the first planarization layer 102 and the first light-emitting element 103. The second planarization layer 104 is in contact with the first light-emitting element 103.

Furthermore, the second planarization layer 104 is in contact with the first opening inner wall 105a. The second planarization layer 104 surrounds the first light-emitting element 103. In other words, the second planarization layer 104 fills the first opening 105 and laterally wraps the first light-emitting element 103. In addition, in the embodiment corresponding to FIG. 1, the second planarization layer 104 extends out of the first opening 105 and partially overlaps a top surface of the first planarization layer 102.

In some embodiments, the first planarization layer 102 and the second planarization layer 104 include a light-transmitting material. In some embodiments, the first planarization layer 102 and the second planarization layer 104 include thermosetting materials or light-cured materials. For example, the first planarization layer 102 and the second planarization layer 104 include ultra high aperture (UHA) materials. For example, some ultra high aperture (UHA) materials include photoactive compounds (PAC), acrylic resin, solvents, and additives. In some embodiments, the photoactive compounds include, for example, an epoxy. In some embodiments, the acrylic resin includes methacrylic acid or the like. In some embodiments, the solvents include mainly propylene glycol monomethyl acetate (PGMEA). The solvents may selectively include methyl ethyl di glycol (MEDG), dipropylene glycol dimethyl ether (DPGDME), methyl 3-methoxypropionate (MMP), or combinations thereof. In some embodiments, adhesion promoters, curing promoters, fluorine-based or silicone-based surfactants, or the like may be included as needed.

In addition, according to the requirements of viscosity and light transmission, the proportion of each composition in the light-transmitting materials of the first planarization layer 102 and the second planarization layer 104 may be adjusted. For example, the proportion of solvent may be adjusted in a way that after the curing process, most of the acrylic resin remains, along with a small amount of photoactive compounds, solvents, and additives.

Thereby, the viscosity of the light-transmitting material is adjusted. In some embodiments, the light transmissions of the first planarization layer 102 and the second planarization layer 104 are in a range of 95% and 99%. Due to the difference in the light transmissions of the first planarization layer 102 and the second planarization layer 104, an interface is observable between the first planarization layer 102 and the second planarization layer 104.

In process operations of some embodiments, before forming the planarization layer(s), mass transfer of the light-emitting elements is performed. For example, as shown in FIG. 1, the first light-emitting element 103 is transferred and connected to the electrode pad 101a in the substrate 101. Next, a light-transmitting material with a high viscosity is coated on the substrate 101 and is exposed to form the first opening 105 and the through hole 120. The exposed light-transmitting material with the high viscosity is further cured or thermoset to form the first planarization layer 102. Then, a light-transmitting material with a low viscosity is coated to fill the first opening 105 and the through hole 120 and is exposed to form the through hole 120 once more. Later, the light-transmitting material with the low viscosity is cured or thermoset to form the second planarization layer 104. Next, a conductive layer 106 is deposited and connects the electrode pad 101b in the substrate 101 with the electrode on a top surface of the first light-emitting element 103 through the through hole 120.

As aforementioned, in some embodiments of the present disclosure, the display device includes an inner planarization layer and an outer planarization layer. First, a material with a high viscosity is used to form the outer planarization layer, i.e., the first planarization layer 102 in FIG. 1, in one process. The outer planarization layer pads the structure to an extent that the outer planarization layer is substantially level with a top surface of the light-emitting element. For example, a height of the outer planarization layer is between 8 μm and 10 μm. In some embodiments, the high viscosity may be greater than 18 centipoise. Later, a material with a low viscosity is used to fill the gap between the outer planarization layer and the light-emitting element until the inner planarization layer extends out of the first opening 105 and covers a top surface of the light-emitting element and part of a top surface of the first planarization layer 102. As such, the inner planarization layer, i.e., the second planarization layer 104 in FIG. 1, is formed. In some embodiments, the low viscosity may be lower than 5 centipoise.

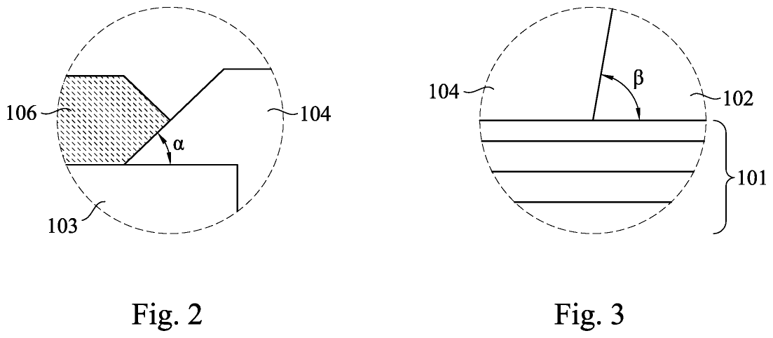

Furthermore, due to differences in viscosities and fluidities between the material of the first planarization layer 102 and the material of the second planarization layer 104, the two light-transmitting materials have different behaviors at their interfaces with other layers. Reference is now made to FIG. 2 and FIG. 3. FIG. 2 and FIG. 3. are partial enlarged views of a circle 2 and a circle 3 of the display device 100A in FIG. 1 according to an embodiment of the present disclosure. According to FIG. 2, a contact angle between the second planarization layer 104 and the first light-emitting element 103 is defined as the contact angle α. According to FIG. 3, a contact angle between the first planarization layer 102 and the substrate 101 is defined as the contact angle β. As shown in FIG. 2 and FIG. 3, the contact angle β is greater than the contact angle α. For example, if an ultra high aperture material with a viscosity of 20 centipoise is used as the material of the first planarization layer 102, the contact angle β may be close to 90°. If an ultra high aperture material with a viscosity of 5 centipoise is used as the material of the second planarization layer 104, the contact angle α may be approximately 30°. As such, referring back to FIG. 1, the contact angle at the interface of the second planarization layer 104 and the top surface of the first light-emitting element 103 is relatively small. Therefore, the taper across the interface of the second planarization layer 104 and the first light-emitting element 103 is relatively gentle. In turn, the structural discontinuity of the conductive layer 106 formed by deposition may be prevented, thereby improving the reliability of the electrical connection of the first light-emitting element 103.

Reference is made back to FIG. 1. In addition, when the first light-emitting element 103 is connected to the substrate in an inverted trapezoid shape as shown in FIG. 1, the material with the low viscosity may better fill the gap between the outer planarization layer and the first light-emitting element 103. Also, the inner planarization layer may adhere to the first light-emitting element 103 to a greater extent, preventing gas from accumulating in unfilled gaps. Blowouts caused by expansion of the gas during subsequent high-temperature processes may be avoided as well.

As shown in FIG. 1, the conductive layer 106 extends from the electrode pad 101b of the substrate 101 along the side wall of the through hole 120. The conductive layer 106 passes through the top surface of the first planarization layer 102 and a top surface of the second planarization layer 104. On top of that, the conductive layer 106 connects to the electrode of the first light-emitting element 103. In some embodiments, the conductive layer 106 includes a transparent conductive layer including indium tin oxide (ITO).

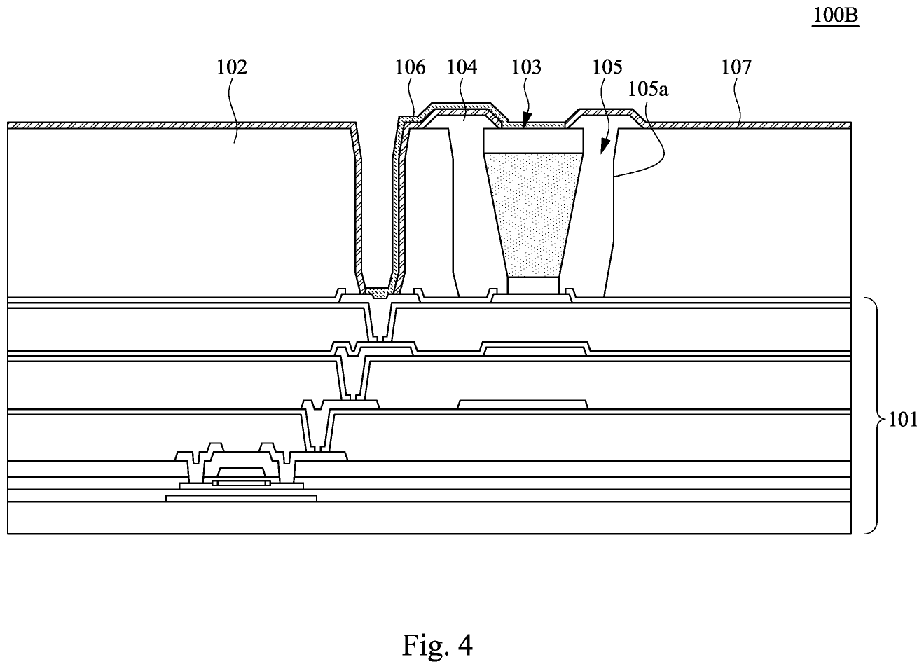

Reference is made to FIG. 4. FIG. 4 is a partial cross-sectional view of a display device 100B according to an embodiment of the present disclosure. The difference between the display device 100B and the display device 100A is that the display device 100B further includes a first protective layer 107 covering the first planarization layer 102 and the second planarization layer 104. The first protective layer 107 may prevent gas escaped from the light-transmitting materials (such as UHA materials) from entering other structures during subsequent processes. In some embodiments, the first protective layer 107 includes silicon nitride (SiN).

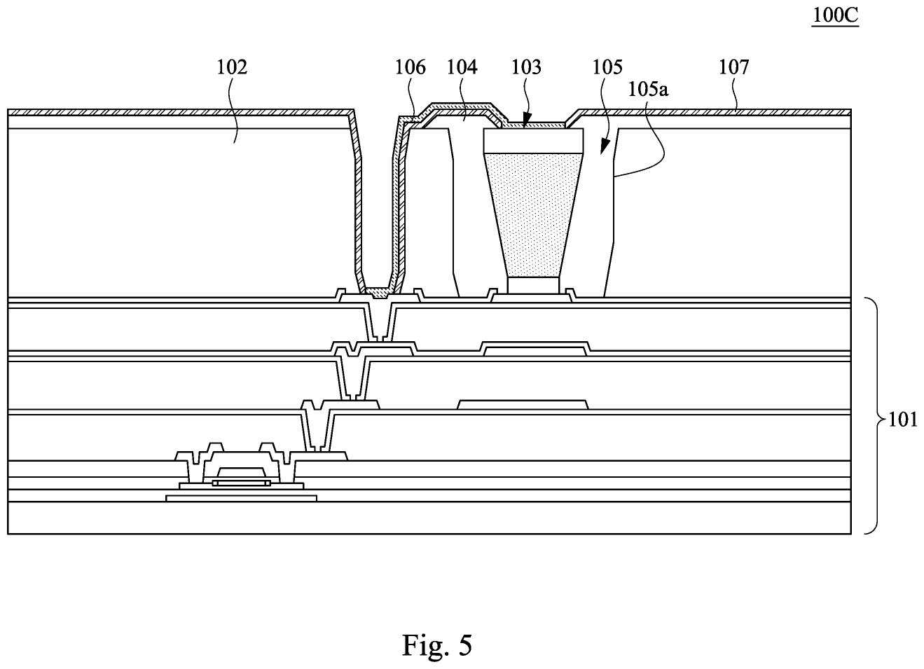

Reference is made to FIG. 5. FIG. 5 is a partial cross-sectional view of a display device 100C according to an embodiment of the present disclosure. The difference between the display device 100C and the display device 100B is that the area of the first planarization layer 102 of the display device 100C covered by the second planarization layer 104 is enlarged. For example, the second planarization layer 104 of the display device 100C is enlarged and connected to a second planarization layer (not shown) of an adjacent light-emitting element. At the same time, the area of the first protective layer 107 of the display device 100C is also expanded to maintain complete coverage of the first planarization layer 102 and the second planarization layer 104. For example, the first protective layer 107 of the display device 100C is expanded to connect with a first protective layer (not shown) of an adjacent light-emitting element.

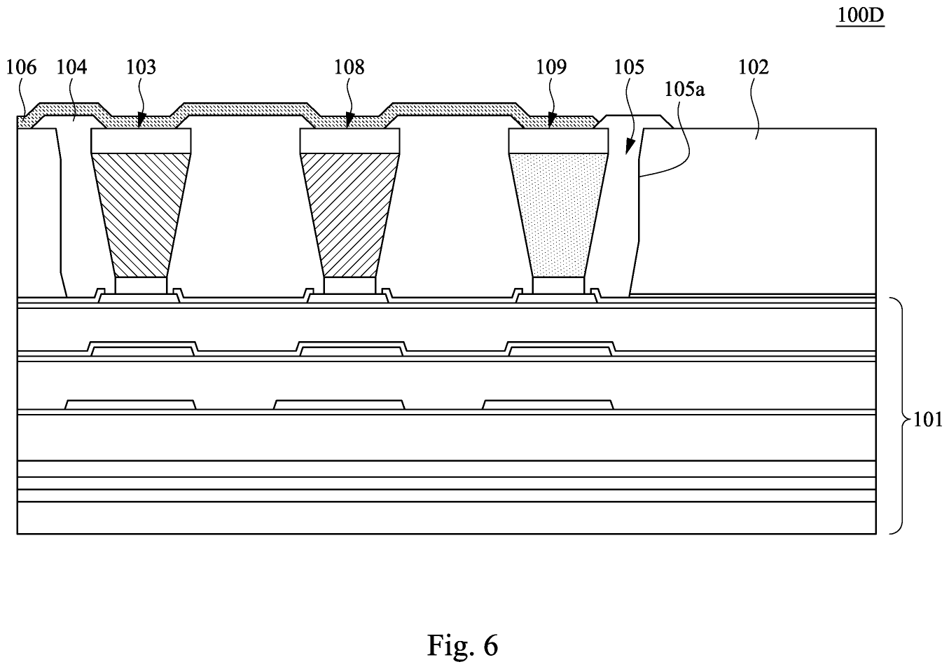

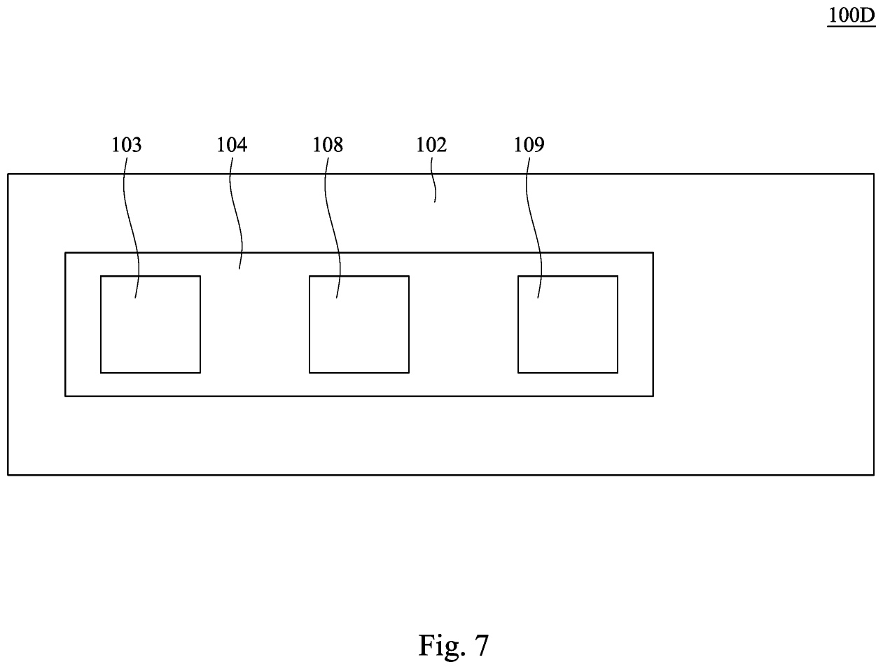

Reference is made to FIG. 6 and FIG. 7. FIG. 6 and FIG. 7 are a partial cross-sectional view and a partial top view of the display device 100D according to an embodiment of the present disclosure, respectively. It should be noted that the conductive layer 106 is not shown in FIG. 7 for clarity. The difference between the display device 100D and the display device 100A is that the display device 100D includes three light-emitting elements in the first opening 105, i.e., the first light-emitting element 103, the second light-emitting element 108, and the third light-emitting element 109. As shown in FIG. 6, the conductive layer 106 extends through the top surface of the first planarization layer 102 and the top surface of the second planarization layer 104. Also, the conductive layer 106 is connected to electrodes of the first light-emitting element 103, the second light-emitting element 108, and the third light-emitting element 109. As shown in FIG. 7, the second planarization layer 104 laterally surrounds the first light-emitting element 103, the second light-emitting element 108, and the third light-emitting element 109. As shown in FIG. 6, portions of the second planarization layer 104 extending out of the first opening 105 overlap portions of edges of the electrodes of the first light-emitting element 103, the second light-emitting element 108, and the third light-emitting element 109. In turn, the continuous structure shown in the top view of FIG. 7 may be obtained.

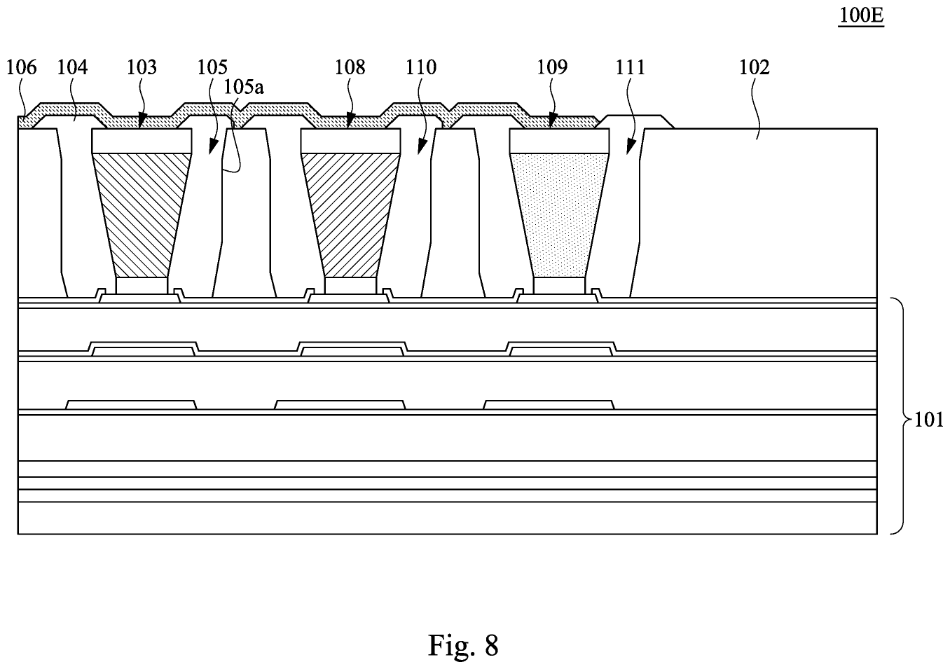

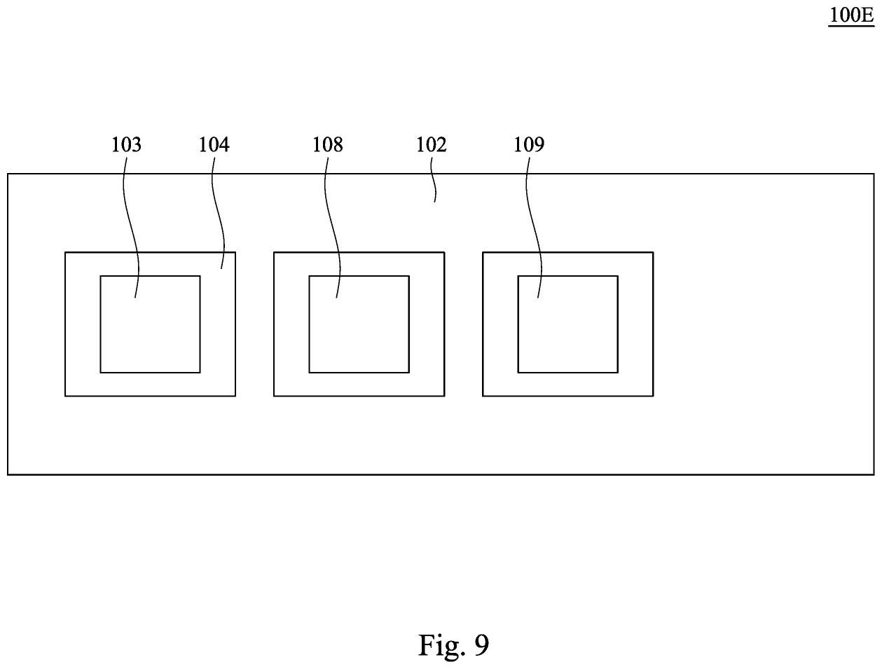

Reference is made to FIG. 8 and FIG. 9. FIG. 8 and FIG. 9 are a partial cross-sectional view and a partial top view of the display device 100E according to an embodiment of the present disclosure, respectively. It should be noted that the conductive layer 106 is not shown in FIG. 9 for clarity. The difference between the display device 100E and the display device 100D is that the display device 100E includes three openings, namely the first opening 105, the second opening 110, and the third opening 111. The first light-emitting element 103 is disposed in the first opening 105. The second light-emitting element 108 is disposed in the second opening 110. The third light-emitting element 109 is disposed in the third opening 111. As shown in FIG. 8 and FIG. 9, the second planarization layer 104 fills the first opening 105, the second opening 110 and the third opening 111. As such, the second planarization layer 104 laterally surrounds the first light-emitting element 103, the second light-emitting element 108, and the third light-emitting element 109 in their corresponding openings. In the embodiment of the display device 100E, although portions of the second planarization layer 104 extending out of the first opening 105, the second opening 110, and the third opening 111 also overlap portions of edges of the electrodes of the first light-emitting element 103, the second light-emitting element 108, and the third light-emitting element 109, the structure is not continuous, as shown in FIG. 8 and FIG. 9.

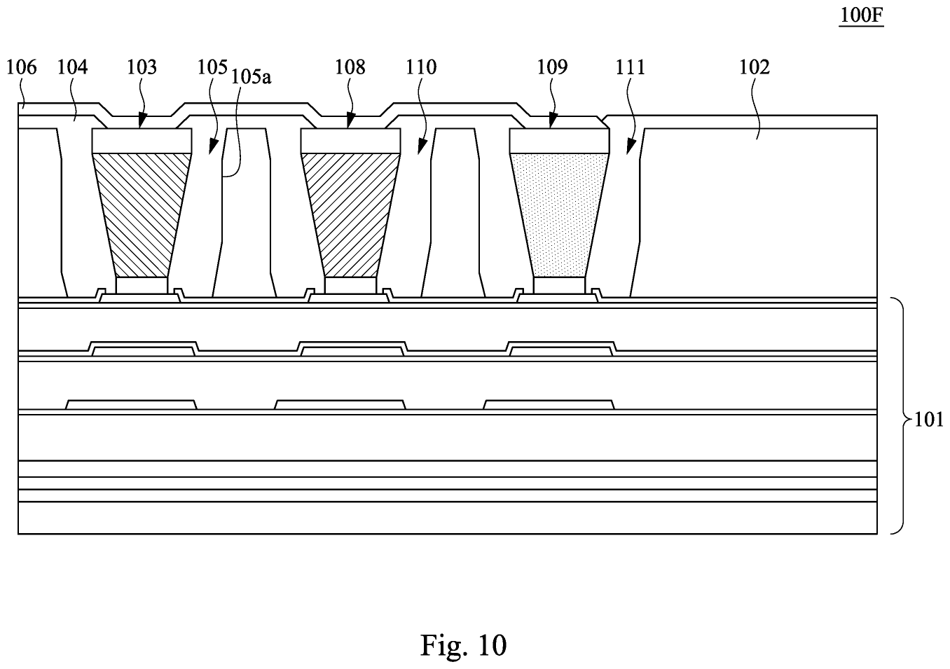

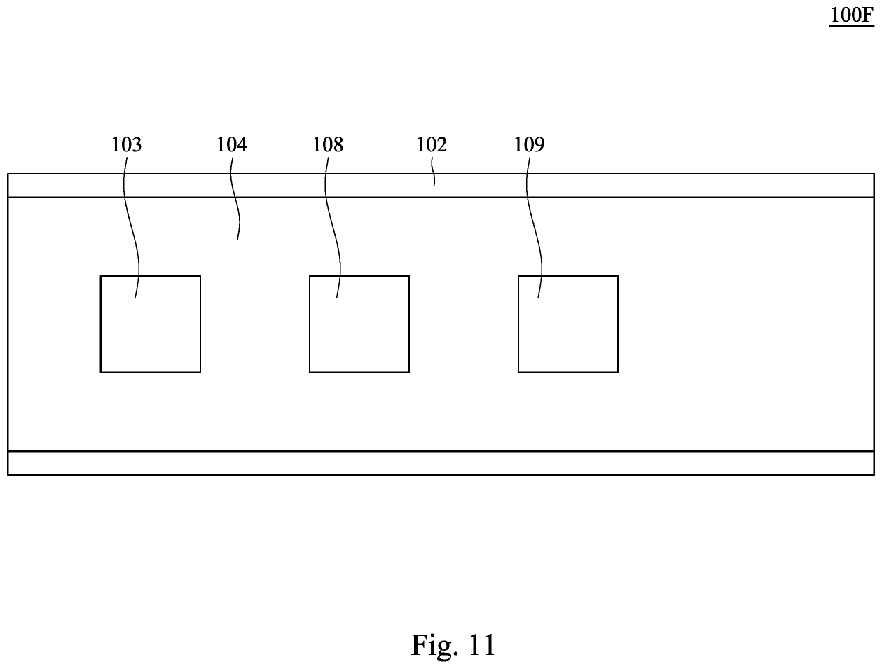

Reference is made to FIG. 10 and FIG. 11. FIG. 10 and FIG. 11 are a partial cross-sectional view and a partial top view of the display device 100F according to an embodiment of the present disclosure, respectively. It should be noted that the conductive layer 106 is not shown in FIG. 11 for clarity. The difference between the display device 100F and the display device 100E is that the second planarization layer 104 of the display device 100F almost completely covers the first planarization layer 102, as shown in FIG. 11.

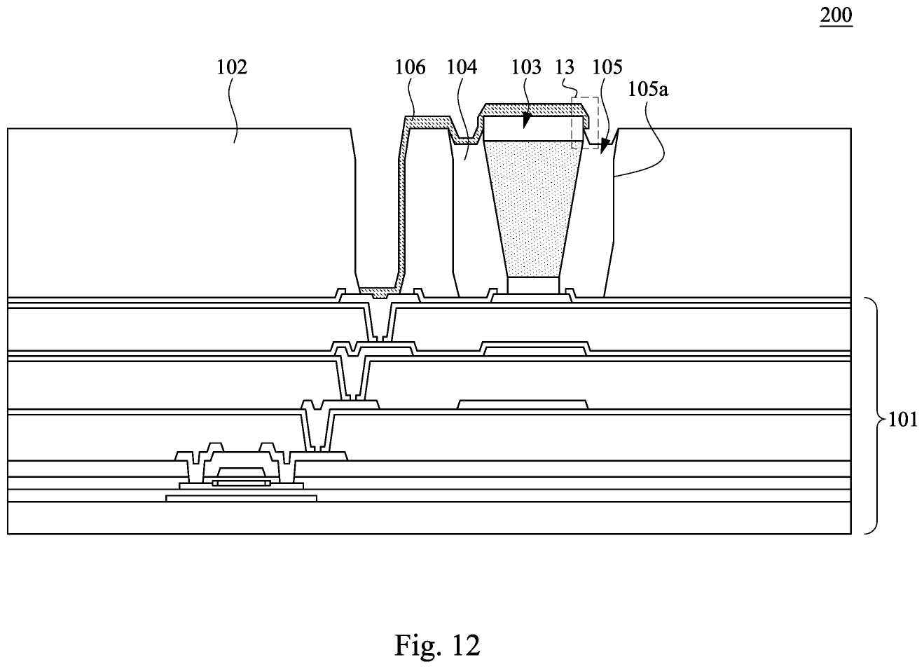

Reference is made to FIG. 12. FIG. 12 is a partial cross-sectional view of a display device 200 according to an embodiment of the present disclosure. The difference between the display device 200 and the display device 100A is that the second planarization layer 104 of the display device 200 fills the first opening 105 to a height so as to contact the electrode of the first light-emitting element 103. The second planarization layer 104 of the display device 200 does not extend out of the first opening 105, nor does it cover the top surface of the first planarization layer 102 as the second planarization layer 104 of the display device 100A does.

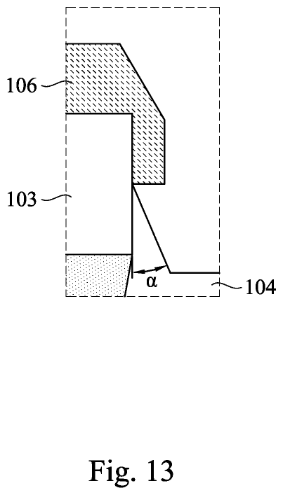

Next, reference is made to FIG. 13. FIG. 13 is a partial enlarged view of a square 13 of the display device 200 in FIG. 12 according to an embodiment of the present disclosure. In this embodiment, a contact angle between the second planarization layer 104 and the first light-emitting element 103 is defined as the contact angle α. The contact angle α is smaller than the contact angle β between the first planarization layer 102 and the substrate 101.

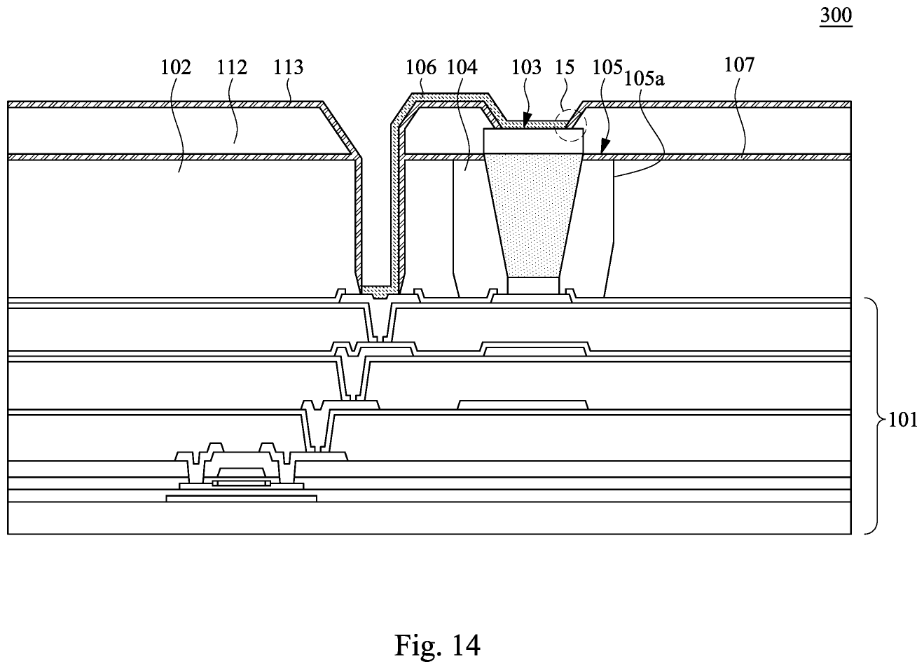

Reference is made to FIG. 14. FIG. 14 is a partial cross-sectional view of a display device 300 according to an embodiment of the present disclosure. The difference between the display device 300 and the display device 100A is that the display device 300 further includes a third planarization layer 112. The third planarization layer 112 at least partially overlaps the top surface of the first planarization layer 102. As shown in FIG. 14, the third planarization layer 112 is in contact with the first light-emitting element 103.

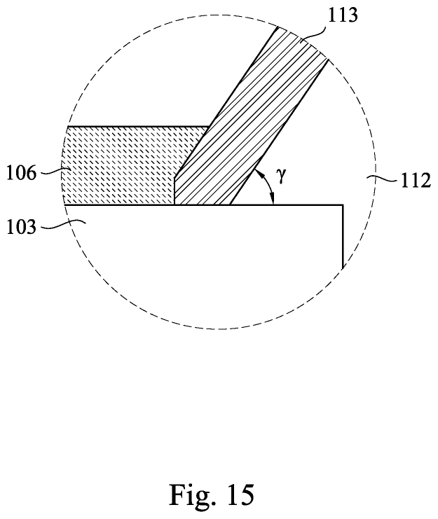

In some embodiments, the third planarization layer 112 includes mainly light-transmitting materials with a low film thickness and a low viscosity, such as UHA materials with a viscosity lower than 5 centipoise. As such, a contact angle γ between the third planarization layer 112 and the first light-emitting element 103 as shown in FIG. 15 is smaller than the contact angle β between the first planarization layer 102 and the substrate 101. FIG. 15 is a partial enlarged view of a circle 15 of the display device 300 in FIG. 14 according to an embodiment of the present disclosure.

Referring back to FIG. 14, the display device 300 further includes a first protective layer 107 covering the first planarization layer 102 and the second planarization layer 104. Furthermore, in some embodiments, the display device 300 further includes a second protective layer 113 covering the third planarization layer 112. In the display device 300, by disposing the first protective layer 107 between the first planarization layer 102 and the third planarization layer 112 as well as between the second planarization layer 104 and the third planarization layer 112, gas may be prevented from escaping and dispersing, as aforementioned. Also, stress may be adjusted through the layer structure as shown, preventing warpage or peeling between the layers caused by stress accumulated in previous and later processes. In some embodiments, the first protective layer 107 and the second protective layer 113 include silicon nitride.

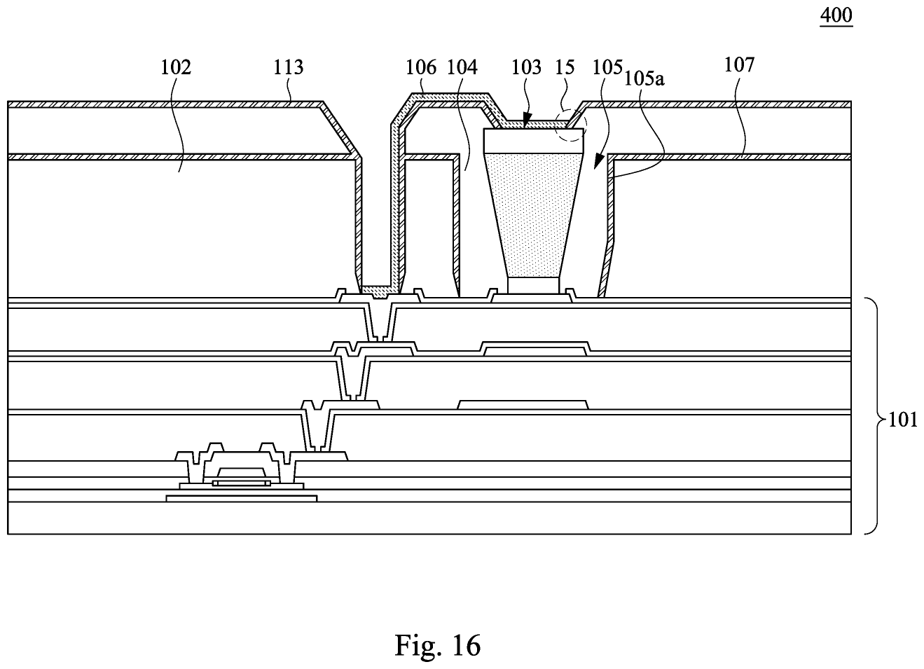

Reference is made to FIG. 16. FIG. 16 is a partial cross-sectional view of a display device 400 according to an embodiment of the present disclosure. The difference between the display device 400 and the display device 100C is that the display device 400 includes a first protective layer 107 and a second protective layer 113. The first protective layer 107 covers the first planarization layer 102. The second planarization layer 104 fills the first opening 105 and extends out of the first opening 105 to cover the first protective layer 107. The second protective layer 113 covers the second planarization layer 104. As aforementioned, the first protective layer 107 and the second protective layer 113 may prevent gas accumulated in the light-transmitting materials from escaping. At the same time, the first protective layer 107 disposed between the first planarization layer 102 and the second planarization layer 104 can further adjust stress between the layers to prevent warping or peeling.

According to the foregoing recitations of the embodiments of the disclosure, it may be seen that in some embodiments of the micro light-emitting diode display devices of the present disclosure, by disposing an inner planarization layer and an outer planarization layers having different viscosities, the structure around the micro light-emitting diodes may be properly padded within two processes, thereby facilitating the formation of the conductive layer as well as the connection and protection of the electrodes of the micro light-emitting diodes. Specifically, an outer planarization layer with a high viscosity is firstly formed in one process to pad the overall structure. Then, an inner planarization layer with a low viscosity is formed in another process to fill the gap around the micro light-emitting diodes and laterally wrap the micro light-emitting diodes. Compared with currently commonly applied technologies, the micro light-emitting diode display devices according to some embodiments of the present disclosure can simplify manufacturing processes and improve productivity while maintaining rigid cover of the micro light-emitting diodes. Moreover, by using materials with a low film thickness and a low viscosity to form the inner planarization layer, a gentle taper can be formed at the interfaces between any two of the inner planarization layer, the light-emitting element, and the outer planarization layer. Thus, the height difference throughout the structure that may adversely affect the electrode connection during the formation of the conductive layer is reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A micro light-emitting diode display device, comprising:
a substrate;
a first planarization layer disposed on the substrate and having a first opening, wherein the first opening has a first opening inner wall;
a first light-emitting element disposed on the substrate, in the first opening, and separated from the first opening inner wall; and
a second planarization layer disposed on the substrate and between the first planarization layer and the first light-emitting element, wherein the second planarization layer is in contact with the first light-emitting element.

2. The micro light-emitting diode display device of claim 1, wherein the second planarization layer is in contact with the first opening inner wall.

3. The micro light-emitting diode display device of claim 1, wherein the second planarization layer surrounds the first light-emitting element.

4. The micro light-emitting diode display device of claim 1, wherein a contact angle between the second planarization layer and the first light-emitting element is smaller than a contact angle between the first planarization layer and the substrate.

5. The micro light-emitting diode display device of claim 1, wherein the second planarization layer extends from the first opening and at least partially overlaps a top surface of the first planarization layer.

6. The micro light-emitting diode display device of claim 1, further comprising a first protective layer covering the first planarization layer and the second planarization layer.

7. The micro light-emitting diode display device of claim 1, further comprising a second light-emitting element and a third light-emitting element, wherein the second light-emitting element and the third light-emitting element are disposed in the first opening.

8. The micro light-emitting diode display device of claim 1, further comprising a second light-emitting element and a third light-emitting element, wherein the first planarization layer further comprises a second opening and a third opening, the second light-emitting element is disposed in the second opening, the third light-emitting element is disposed in the third opening, and the second planarization layer is disposed in the second opening and the third opening.

9. The micro light-emitting diode display device of claim 1, further comprising a third planarization layer, wherein the third planarization layer at least partially overlaps a top surface of the first planarization layer and is in contact with the first light-emitting element.

10. The micro light-emitting diode display device of claim 9, further comprising a first protective layer covering the first planarization layer and the second planarization layer.

11. The micro light-emitting diode display device of claim 10, further comprising a second protective layer covering the third planarization layer.

12. The micro light-emitting diode display device of claim 9, wherein a contact angle between the third planarization layer and the first light-emitting element is smaller than a contact angle between the first planarization layer and the substrate.

13. The micro light-emitting diode display device of claim 1, wherein at least one of the first planarization layer and the second planarization layer comprises a light-transmitting material.

14. The micro light-emitting diode display device of claim 1, wherein a light transmission of the first planarization layer and a light transmission of the second planarization layer are in a range of 95% and 99%.

15. The micro light-emitting diode display device of claim 1, wherein the first planarization layer and the second planarization layer comprise acrylic resin.

16. A micro light-emitting diode display device, comprising:
a substrate;
a first planarization layer disposed on the substrate and having a plurality of openings with corresponding opening inner walls;
a plurality of light-emitting elements disposed on the substrate and separated from the corresponding opening inner walls of the plurality of openings; and
a second planarization layer disposed in the plurality of openings, wherein the second planarization layer is in contact with the corresponding opening inner walls of the plurality of openings, the second planarization layer laterally wraps the plurality of light-emitting elements, and the second planarization layer is in contact with each of the plurality of light-emitting elements.

17. The micro light-emitting diode display device of claim 16, wherein a top surface of the first planarization layer is substantially level with a top surface of at least one of the plurality of light-emitting elements.

18. The micro light-emitting diode display device of claim 16, wherein a contact angle between the second planarization layer and at least one of the plurality of light-emitting elements is smaller than a contact angle between the first planarization layer and the substrate.

19. The micro light-emitting diode display device of claim 16, wherein each of the plurality of light-emitting elements corresponds to one of the plurality of openings and is disposed in its corresponding opening.

20. The micro light-emitting diode display device of claim 16, wherein at least two of the plurality of light-emitting elements are disposed in one of the plurality of openings, and the second planarization layer is disposed between any adjacent two light-emitting elements in the one of the plurality of openings.
